(19) United States
(12) Patent Application Publication
(10) Pub. No.: US 2012/0069542 A1
(43) Pub. Date: Mar. 22, 2012

(54) Communication module

(75) Inventor: Tetsuo Ishizaka, Kawasaki (JP)

(73) Assignee: FUJITSU OPTICAL COMPONENTS LIMITED, Kawasaki-shi (JP)

(21) Appl. No.: 13/067,665

(22) Filed: Jun. 17, 2011

(30) Foreign Application Priority Data
Sep. 16, 2010 (JP) 2010-207603

(51) Int. Cl. H05K 9/00

(52) U.S. Cl. 361/818

(57) ABSTRACT

A communication module includes a communication circuit, a connector coupled to the communication circuit, a housing having a space for arranging the communication circuit and an aperture for arranging the connector, and a projection provided at facing inside wall surface of the housing and attenuating an electromagnetic wave within a frequency range transmitted in the space.

### CROSS-REFERENCE TO RELATED APPLICATION

This application is based upon and claims the benefit of priority of the prior Japanese Patent Application No. 2010-207603, filed on Sep. 16, 2010, the entire contents of which are incorporated herein by reference.

### FIELD

The present disclosure relates to the art of suppressing the leakage of electromagnetic waves from communication modules, for example, relates to a communication module which suppresses leakage of electromagnetic waves from a housing to which a connector is plugged.

### BACKGROUND

In a communication module such as a pluggable high speed communication module enabling hot plug-in, an aperture for plugging in a hot plug connector is provided. The communication module has an electromagnetic wave generation source inside the housing. If electromagnetic waves which are generated at the electromagnetic wave generation source leak from the aperture of the housing, electromagnetic interference (EMI) will be caused. In a communication device using such a communication module, it is demanded that EMI standards be satisfied in the state mounting multiple channels of modules.

In regard to the communication module, it is known to form a discharge-use projection made of conductive material at the inside surface of a housing provided with an optical connector and at the front surface of the housing (see Japanese Laid-open Patent Publication No. 2007-93908).

In this regard, the aperture at the housing of a communication module is essential for connection with a communication device by a connector. This aperture cannot be closed. To suppress electromagnetic waves which leak from a housing provided with such an aperture, the measure of placing an electromagnetic wave absorber in the aperture has been employed, but provision of such an electromagnetic wave absorber increases the parts costs and assembly costs. Further, even if providing an electromagnetic wave absorber, it is not possible to prevent leakage of electromagnetic waves from a signal line which is led out from the aperture.

### SUMMARY

The present disclosure provides a communication module. The communication module includes a communication circuit, a connector coupled to the communication circuit, a housing having a space for arranging the communication circuit and an aperture for arranging the connector, and projection provided at facing inside wall surface of the housing and attenuating an electromagnetic wave within a range of frequency transmitted in the space.

The object and advantages of the embodiments will be realized and attained by means of the elements and combinations particularly pointed out in the claims.

It is to be understood that both the foregoing general description and the following detailed description are exemplary and explanatory and are not restrictive of the embodiments, as claimed.

### BRIEF DESCRIPTION OF DRAWINGS

FIG. 1 is a cross-sectional view illustrating one example of a pluggable communication module according to a first embodiment;

FIG. 2 is a view illustrating one example of an internal structure of a pluggable communication module;

FIG. 3 is a view illustrating one example of an electromagnetic wave attenuation structure;

FIG. 4 is a view illustrating an attenuated state of electromagnetic waves;

FIG. 5 is a view illustrating an amount of attenuation of electromagnetic waves in accordance with a length of electromagnetic wave attenuation parts;

FIG. 6 is a view illustrating an electromagnetic wave attenuation characteristic of electromagnetic wave attenuation parts;

FIG. 7 is a disassembled perspective view illustrating one example of a housing and electromagnetic wave attenuation parts of a pluggable communication module according to a second embodiment;

FIG. 8A and FIG. 8B are views illustrating a housing of a pluggable communication module which is provided with electromagnetic wave attenuation parts;

FIG. 9 is a disassembled perspective view illustrating one example of a housing and electromagnetic wave attenuation parts of a pluggable communication module according to a third embodiment;

FIG. 10 is a view illustrating a housing of a pluggable communication module which is provided with electromagnetic wave attenuation parts;

FIG. 11 is a perspective view illustrating one example of a housing of a pluggable communication module according to a fourth embodiment;

FIG. 12 is a view illustrating electromagnetic wave attenuation and a cutoff frequency of a housing;

FIG. 13 is a perspective view illustrating one example of a housing of a pluggable communication module according to a fifth embodiment;

FIG. 14 is a view illustrating electromagnetic wave attenuation and a cutoff frequency of a housing;

FIG. 15 is a perspective view illustrating an embodiment of a pluggable communication module;

FIG. 16 is a disassembled perspective view illustrating an embodiment of a pluggable communication module;

FIG. 17 is a perspective view illustrating a housing according to a comparative example of an XFP module;

FIG. 18 is a view illustrating a spread of electromagnetic waves (center frequency 5 GHz short pulse) inside a housing of an XFP module; and

FIG. 19 is a view illustrating a spread of electromagnetic waves (center frequency 10 GHz short pulse) inside a housing of an XFP module.

### DESCRIPTION OF EMBODIMENTS

Additional objects and advantageous of the disclosure will be set forth in part in the description which follows, and in part will be obvious from the description, or may be learned by practice of the invention. The object and advantages of the invention will be realized and attained by means of the elements and combinations particularly pointed out in the appended claims. It is to be understood that both the foregoing general description and the following detailed description are exemplary and explanatory only and are not restrictive of the invention, as claimed.

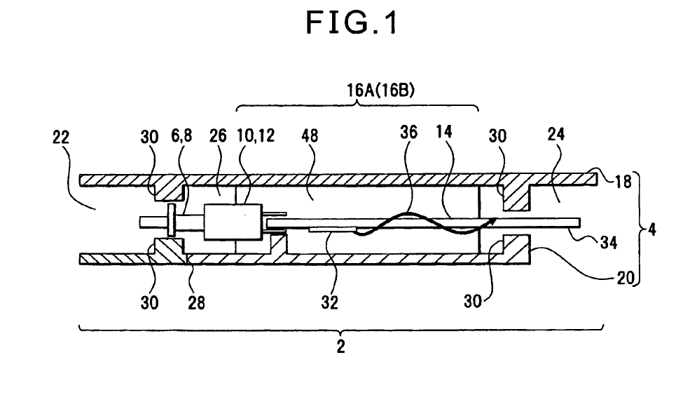

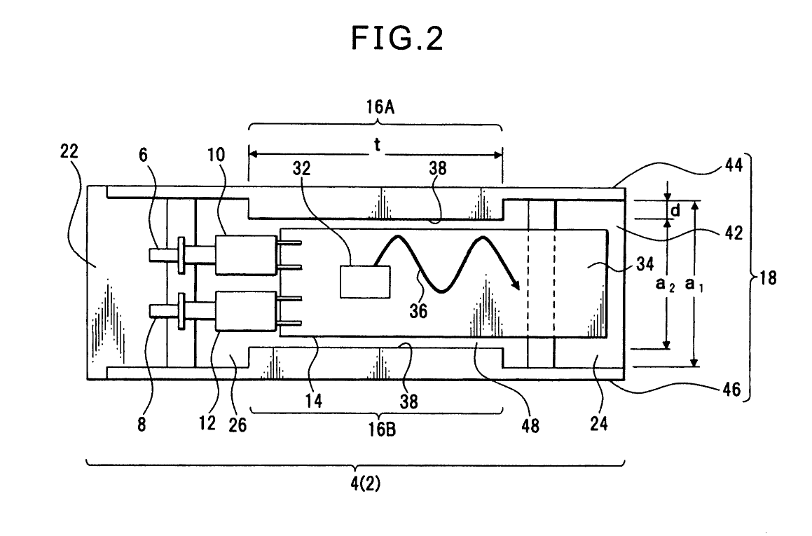

FIG. 1 illustrates a longitudinal cross-section of one example of a pluggable communication module according to a first embodiment, while FIG. 2 illustrates one example of the internal structure of the pluggable communication module.

A communication module 2 is a communication module enabling hot plug-in. The communication module 2, as shown in FIG. 1 and FIG. 2, is provided with a housing 4, optical connectors 6 and 8, an optical transmitter 10, an optical receiver 12, a circuit board 14, and electromagnetic wave attenuation parts 16A and 16B.

The housing 4 is formed by a multisided tubular member comprised of zinc, stainless steel, or another metal, that is, a main body 18, and a lid 20. A front aperture 22 is provided at its front side, while a back aperture 24 is provided at its back side. These front aperture 22 and back aperture 24 are interfaces for connection by connectors between the communication module 2 and the outside device. Further, the main body 18 has a plate part and side plates to provide a first space 26 in which the circuit board 14 are set. A window 28 at the main body 18 has the openable and closable lid 20.

In the space 26 which is formed by the main body 18 and the lid 20, optical components, that is, the optical connectors 6 and 8 and the circuit board 14, are arranged. The optical components are supported by support parts 30 which are provided at the main body 18 and the lid 20. At the circuit board 14, the optical transmitter 10 and optical receiver 12 and other circuit components are arranged.

The optical connectors 6 and 8 are arranged at the housing 4 at the front aperture 22 and are coupled with waveguides, that is, optical fibers. In this embodiment, the optical connector 6 is coupled to the optical transmitter 10 and sends out light which are emitted from the optical transmitter 10. Further, the optical connector 8 is coupled to optical receiver 12 and receives light from the optical fiber.

The optical transmitter 10 is provided with a light source which generates laser light, that is, a laser diode (LD) or other light emitting device. The optical receiver 12 is provided with a photo detection unit which detects laser light, that is, a photo detector (PD). The optical transmitter 10 and optical receiver 12 are coupled to the circuit board 14 and are arranged at the front aperture 22 in the housing 4.

At the circuit board 14, as a means for driving the laser diode (LD) of the optical transmitter 10, an LD driver 32 is arranged. Further, a transmission circuit and a reception circuit are provided. The LD driver 32 is a means for driving the laser diode of the optical transmitter 10 and is an electromagnetic wave generation source which emits high frequency band electromagnetic waves 36. Further, at the circuit board 14 a connector 34 is formed. This connector 34 is exposed from the back aperture 24 while spaced away from the housing 4 for insulation purposes and may be plugged into a connector of a host side circuit board.

The electromagnetic wave attenuation parts 16A and 16B are placed inside the housing 4 which contains the electromagnetic wave generation source and cause the electromagnetic waves 36 to attenuate. The electromagnetic wave attenuation parts 16A and 16B establish an attenuation region having a predetermined cutoff frequency inside of the housing 4 utilizing spatial resonance. In the first embodiment, for the cutoff frequency fc₁ of the space 26 of the housing 4, the electromagnetic wave attenuation parts 16A and 16B establish an attenuation region of a cutoff frequency fc₂ (>fc₁) at the space 26 of the housing 4 and cause attenuation of electromagnetic waves 36 of a cutoff frequency fc₂ or less. The electromagnetic wave attenuation parts 16A and 16B specifically provide projections 38 which are provided at facing inside wall surfaces of the main body 18. Two projections 38 are placed so as to sandwich the circuit board 14 between them. The aperture width of the space determined by the two projections 38 determines the cutoff frequency fc₂ corresponding to the leaking electromagnetic waves 36. The lengths of the projections 38 along the inside wall surfaces of the main body 18 determines the length of the electromagnetic wave attenuation region in which the electromagnetic waves 36 propagate and attenuate.

In the communication module 2, the housing 4 is made using a metal material, so the space 26 forms a rectangular waveguide and has an existing cutoff frequency fc₁. As opposed to this, the projections 38 which are set in the space 26 are formed by the same material as the housing 4. The aperture width and length of the region in which the projections 38 are set are set so as to form a filter having a specific cutoff frequency fc₂ and a specific band width and form an attenuator. Therefore, it is possible to prevent leakage of electromagnetic waves of a cutoff frequency fc₂ or less which is set by the electromagnetic wave attenuation parts 16A and 16B.

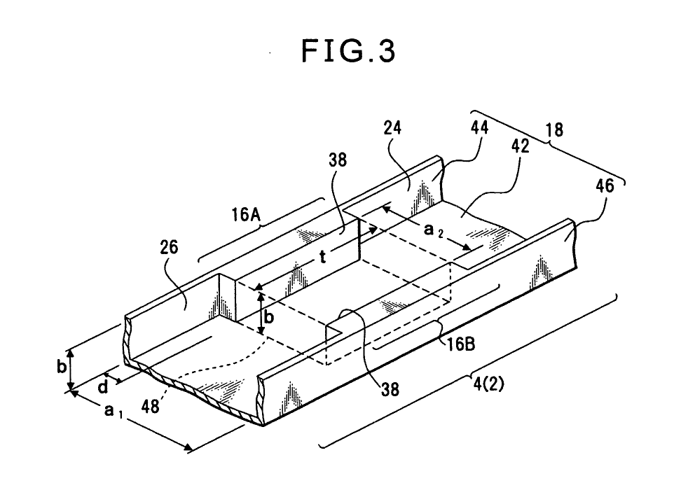

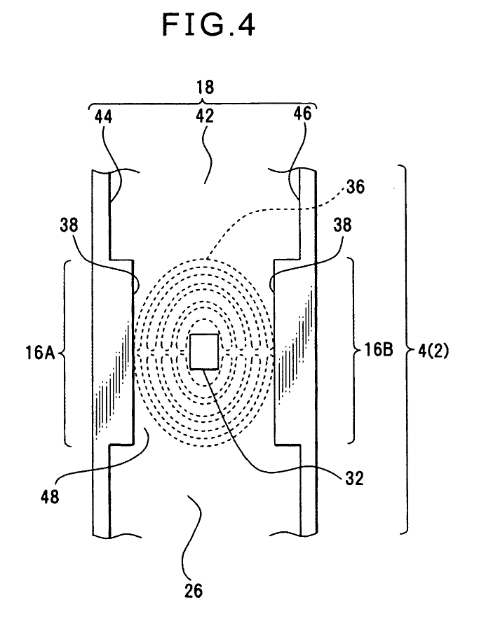

FIG. 3 shows the shape of the space inside the housing, while FIG. 4 shows the attenuated state of the electromagnetic waves. First, the cutoff frequency fc₁ of a housing 4 which is not provided with the electromagnetic wave attenuation parts 16A and 16B will be explained.

The housing 4 is box-shaped. The space 26 of the housing 4 forms a rectangular waveguide. This space 26 is formed by the plate part 42, side plates 44 and 46, and lid 20 of the main body 18. If designating the width of the interval between the side plates 44 and 46 (space width of space 26) as “a₁” and designating the short width of the side plates 44 and 46 as “b”, the cutoff frequency fc₁ of the space 26 becomes

fc₁=(c/2π){(mπ/a₁)²+(nπ/b)²}^{1/2} (1)

In equation (1), “c” is the speed of light (2.998×10⁸ m/s), and the coefficients “m” and “n” are integers satisfying m, n≧0.

In equation (1), if a₁>b, the cutoff frequency is determined by the long side dimension a₁, so

fc₁≈c/2a₁ (2)

If making a₁=15 mm, from equation (2),

fc₁≈c/2a₁=2.998×10⁸/0.0015×2≈9.94 GHz (3)

The shape of the space set in the housing 4, that is, in this embodiment, the space width, is used to determine the spatial resonance frequency. Due to this, the inherent propagation frequency is determined and the cutoff frequency is determined. Thus, from the spatial shape (empty space) of the space 26, theoretically electromagnetic waves of a frequency of 9.94 GHz or less cannot be propagated. However, in actuality, sometimes electromagnetic waves 36 of a frequency of the cutoff frequency 9.94 GHz or less are spuriously emitted to the outside of the housing 4 from the back aperture 24. If the housing 4 is short in length, leakage of electromagnetic waves 36 of a frequency of the cutoff frequency 9.94 GHz or less is liable to occur.

In this way, the housing 4 forming the rectangular waveguide is a filter for the electromagnetic waves 36 which are emitted from the LD driver part 32. Further, for spurious emissions from the back aperture 24, the back aperture 24 does not have the function of suppressing electromagnetic waves 36. Spurious emissions of electromagnetic waves 36 will occur from the housing 4 through the aperture 24.

If the frequency of the electromagnetic waves 36 which are emitted from the LD driver part 32 is known (in actuality, the frequency is already known by measurement), it is possible to reduce the EMI from the housing 4 to the outside by optimizing the spatial resonance frequency of the transmission path formed by the space 26 of the housing 4.

Next, the cutoff frequency fc₂ of the electromagnetic wave attenuation parts 16A and 16B will be explained.

If providing the electromagnetic wave attenuation parts 16A and 16B inside of the housing 4, as shown in FIG. 3, a second space 48 which differs in space width from the space 26 is formed. The region of the second space 48 also forms a rectangular waveguide in the space 26. In the second space 48, when the interval between the projections 38 which are formed at the insides of the side plates 44 and 46 which form the space 26 (second space width) is designated as “a₂” (<a₁) and the short width of the projections 38 is designated as “b”, the second space width a₂ becomes smaller than the space width a₁ by exactly two times the thickness of the projections 38.

If designating the thickness of the projections 38 as “d”, the second space width a₂ is

a₂=a₁−2d<a₁ (4)

Therefore, the cutoff frequency fc₂ in the case of the space width of the second space 48 provided with the electromagnetic wave attenuation parts 16A and 16B, that is, the second space width a₂, becomes

fc₂=(c/2π){(mπ/a₂)²+(nπ/b)²}^{1/2} (5)

In equation (5) as well, “c” and the coefficients “m” and “n” are the same as those of the equation (1).

This cutoff frequency fc₂, from the relationship of equation (4), becomes

fc₂>fc₁ (6)

In equation (5), if a₂>b, in the same way as equation (2), the cutoff frequency is determined by the long side dimension a₂, so

fc₂≈c/2a₂ (7)

Here, if making a₁=15 mm and d=1.5 mm, the second space width a₂, from equation (4), becomes a₂=13 mm. In this case, the cutoff frequency fc₂, from equation (7), becomes

fc₂≈c/2a₂=2.998×10⁸/0.0013×2≈11.5 GHz

That is, due to the electromagnetic wave attenuation parts 16A and 16B, the electromagnetic waves of a frequency of 11.5 GHz or less are attenuated.

At the second space 48 of the electromagnetic wave attenuation parts 16A and 16B, if the distance of propagation of the electromagnetic waves 36 is short, there is a possibility that the electromagnetic waves of a cutoff frequency fc₂ or less will not be sufficiently attenuated. Therefore, the length “t” of the long direction of the electromagnetic wave attenuation parts 16A and 16B may be determined so that the desired attenuation occurs in the electromagnetic waves 36. FIG. 4 is a view which illustrates the attenuated state of the electromagnetic waves.

This attenuation amount is given by

Attenuation amount=−10 log(−αt)=8.6859 αt dB (8)

In equation (8), α is the attenuation coefficient, while “t” is the length of the electromagnetic wave attenuation parts 16A and 16B along the walls inside the body. The attenuation amount increases in proportion to the product of the attenuation coefficient α and the length “t”.

The attenuation coefficient α is

α={(π/a₂)²−k²}/2 (9)

In equation (9) k=ω/c=2πfc/c.

If finding the attenuation amount at the section (attenuation region) of the electromagnetic wave attenuation parts 16A and 16B of the length “t” of the projections 38 for an electromagnetic wave 36 of the frequency 10 GHz, if frequency fc=10 GHz,

k=ω/c=2πfc/c=2π×10×10⁹÷2.998×10⁸=209.58 (10)

The attenuation coefficient α, if a₂=13 mm, from equation (9), becomes

α={(π/0.013)²−209.58²}÷2=120.317

Due to this, the attenuation amount with respect to the length “t” becomes:

Attenuation amount=8.6859×120.312×t dB (11)

This increases in proportion to the length “t”.

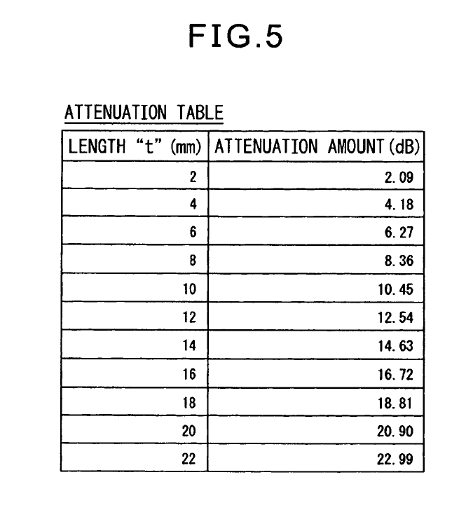

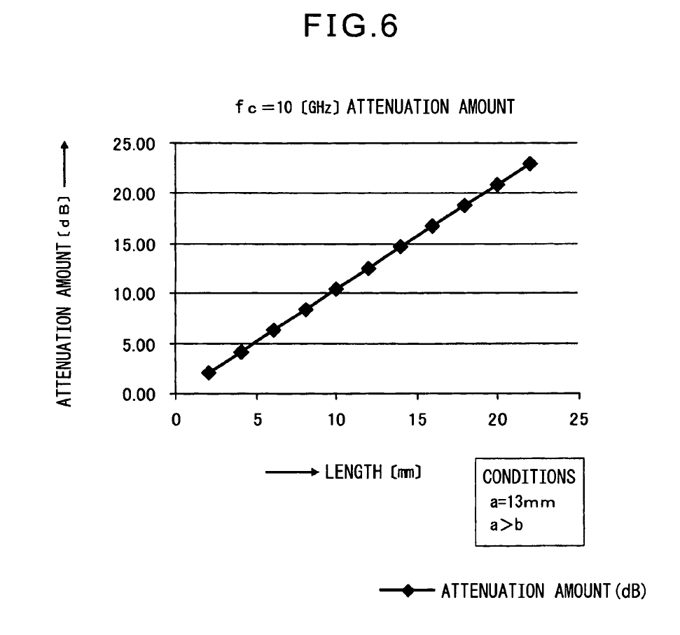

From this relationship, if making the attenuation amount (dB), of the electromagnetic waves of the frequency 10 GHz, a₂=13 mm, as shown in FIG. 5 and FIG. 6, the attenuation amount increases in proportion to the length “t” of the electromagnetic wave attenuation parts along the inside walls of the housing. FIG. 5 is an example of an attenuation table which shows the relationship between the length “t” and the attenuation amount (dB), while FIG. 6 illustrates an example of an attenuation line which illustrates the relationship between a length “t” and an attenuation amount (dB).

In the communication module 2, the electromagnetic wave attenuation parts 16A and 16B which are provided inside of the housing 4 can be used to attenuate the electromagnetic waves 36. It is therefore possible to suppress spurious emissions of electromagnetic waves 36 from the back aperture 24.

As explained above, the features and effects of the first embodiment are as follows:

(1) The housing 4, which can be deemed to be a rectangular waveguide, has projections 38 set inside the housing 4. The cutoff frequency fc is determined by the space width and length of the region where the projections 38 are set. If the region which is set by the cutoff frequency fc and the length “t” of the projections 38 is formed to include the electromagnetic wave generation (emission) source (in this case, the LD driver 32), it is possible to attenuate the electromagnetic waves 36 which are emitted from the LD driver 32. Thus, the width a₂ between the projections 38 is set and a narrowed part inside of the housing is provided.

The narrower the width a₂ is, the higher the cutoff frequency is.

(2) By providing the electromagnetic wave attenuation parts 16A and 16B, it is possible to cause the electromagnetic waves 36 to attenuate, prevent spurious emissions of electromagnetic waves 36, and improve the EMI characteristics of the communication module 2.

(3) In particular, it is sufficient to set the electromagnetic wave attenuation parts 16A and 16B between the electromagnetic wave generation source which causes the spurious emissions at the time of driving the communication module 2 and the back aperture 24.

(4) In the communication module 2, it is possible to shift the cutoff frequency in accordance with the frequency of the generated electromagnetic waves 36 and possible to suppress EMI to the outside.

(5) It is possible to change the attenuation amount by the cutoff frequency, which is determined by the projections 38 of the housing 4, and the length “t” of the projections 38.

(6) The projections 38, which are examples of the electromagnetic wave attenuation parts 16A and 16B, may be members formed integrally with the main body 18 of the housing 4 or may be members which are separate from the main body 18 of the housing 4. If the projections 38 are made integral with the main body 18, it is possible to form the projections 38 at the stage of forming the main body 18 and possible to make the main body 18 and the housing 4 sturdier. Further, if the projections 38 are separate members from the main body 18 of the housing 4, they can be freely replaced. For example, by changing the projections 38 to ones of a desired length, it is possible to adjust (for example, increase or decrease) the cutoff frequency and the amount of attenuation of the electromagnetic waves.

(7) In the above embodiment, an effective measure can be taken against EMI without use of an electromagnetic wave absorber or otherwise increasing the number of parts like in the past.

### A Second Embodiment

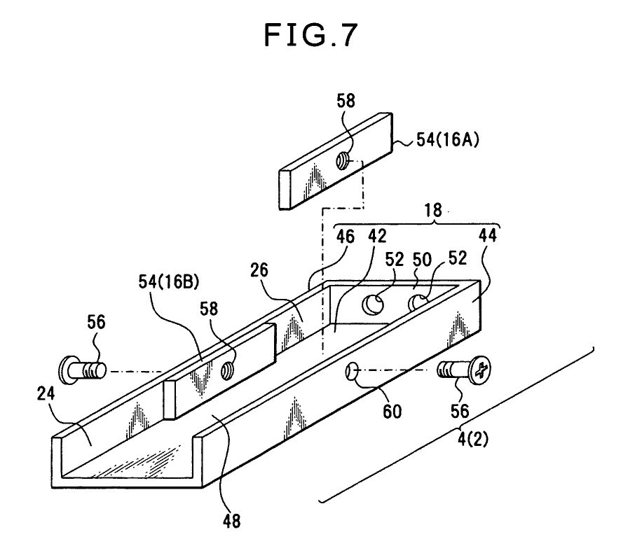

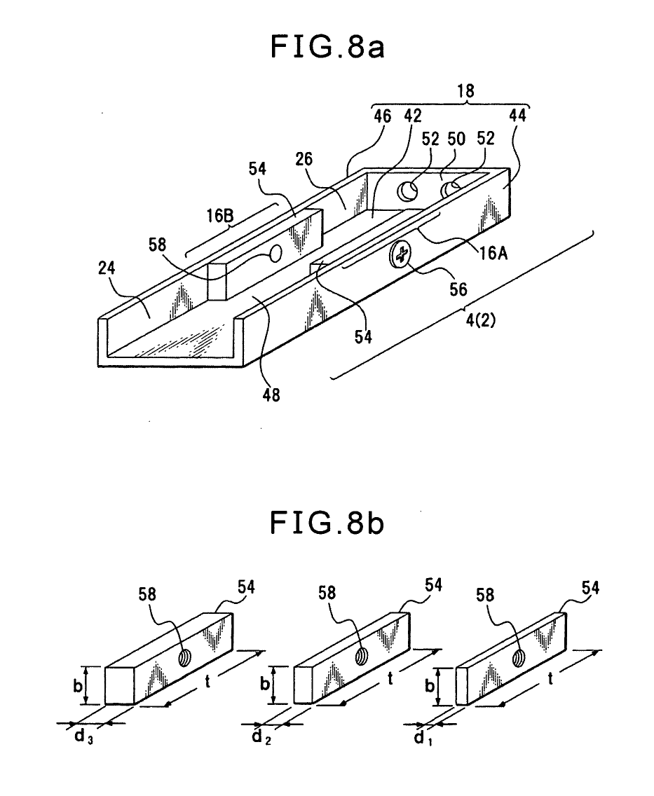

FIG. 7 illustrates a housing and attenuation blocks of a communication module according to a second embodiment, while FIG. 8A and FIG. 8B illustrate a housing provided with attenuation blocks. In FIG. 7 and FIGS. 8A and 8B, parts the same as in FIG. 1 and FIG. 2 are assigned the same reference notations.

In the second embodiment, the housing 4 of the communication module 2, as shown in FIG. 7 and FIGS. 8A and 8B, is a box shape which is comprised of a rectangular shaped plate part 42 in the long direction of which side plates 44 and 46 are provided and in the short direction of which a side plate 50 and a lid (not shown) are provided. The side plate 50 is formed with apertures 52 for leading out connectors 6 and 8.

The electromagnetic wave attenuation parts 16A and 16B are respectively provided with attenuation blocks 54. The attenuation blocks 54 are formed with screw holes 58 for fastening by setscrews 56. The side plates 44 and 46 are formed with through holes 60 for passing the setscrews 56. The attenuation blocks 54 may be comprised of metal or another good conductor the same as the housing 4.

As shown in FIG. 8A, attenuation blocks 54 are placed at the inner wall surfaces of the side plates 44 and 46 of the housing 4. Specifically, the screw holes 58 of the attenuation blocks 54 are aligned with the through holes 60, and setscrews 56 are passed through the through holes 60 from outside the housing 4 and attached to the screw holes 58. If fastening the attenuation blocks 54 to the inside of the housing 4, the electromagnetic wave attenuation parts 16A and 16B are formed in the space 26 of the housing 4. The attenuation blocks 54 are made equal in electrical potential with the housing 4 by joining them to the housing 4 by the setscrews 56.

The attenuation blocks 54, as shown in FIG. 8B, are preferably prepared in several types of different widths “d” for the height “b”, for example, d₁, d₂, and d₃ (d₁<d₂<d₃). By selecting the widths d₁, d₂, and d₃, it is possible to obtain different cutoff frequencies fc. The space widths a₃, a₄, and a₅ of the space 48 between the electromagnetic wave attenuation parts 16A and 16B, from equation (4), become:

a₃=a₁−2d₁ (12)

a₄=a₁−2d₂ (13)

a₅=a₁−2d₃ (14)

whereby different cutoff frequencies fc₃, fc₄, and fc₅ (fc₃>fc₄>fc₅) are set.

If, like in the second embodiment, making the projections 38 (FIG. 2 and FIG. 3) separate from the housing 4 and detachable, it is possible to select attenuation blocks 54 having the desired widths and change the cutoff frequency.

In the case of the plurality of attenuation blocks 54 which are illustrated in FIG. 8B, if setting the attenuation blocks 54 to the same length “t”, it is possible to make the attenuation amounts of the electromagnetic waves the same. By changing the length “t” of the attenuation blocks 54 or replacing the attenuation blocks 54 with ones of different lengths “t”, it is possible to adjust the attenuation amount of the electromagnetic waves 36 in the housing 4.

### A Third Embodiment

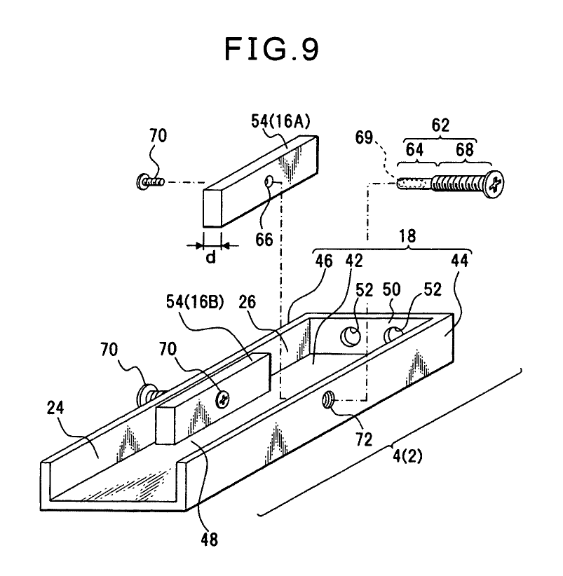

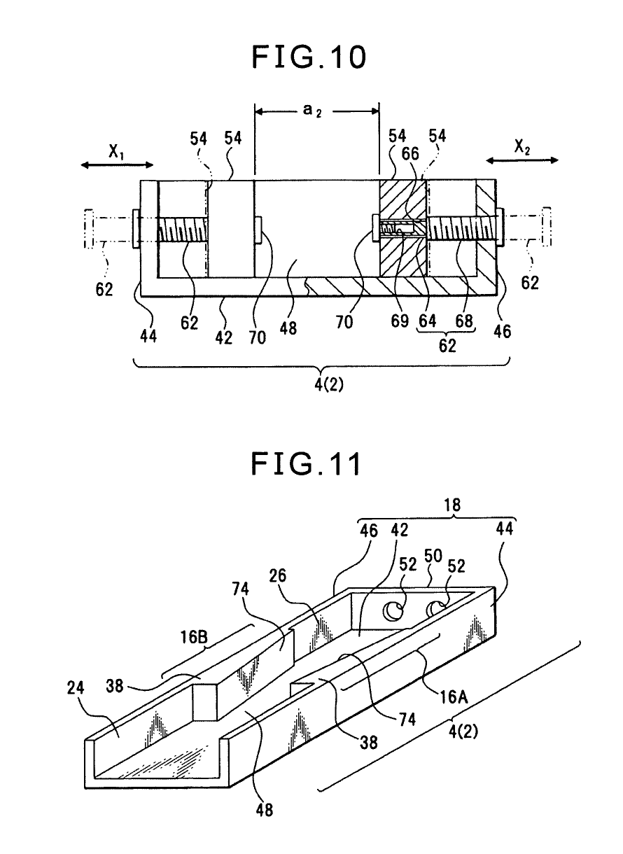

FIG. 9 illustrates a housing and attenuation block members of a communication module according to a third embodiment, while FIG. 10 illustrates an adjusted state of amounts of projection of the attenuation block members. In FIG. 9 and FIG. 10, parts the same as in FIG. 7 and FIG. 8 are assigned the same reference notations.

In the second embodiment, different width d (d₁, d₂, and d₃) attenuation blocks 54 are used. However, in the third embodiment, as shown in FIG. 9, attenuation blocks 54 having a fixed width “d” are used and the mounting positions of the attenuation blocks 54 are made changeable to change the interval between the attenuation blocks 54.

The attenuation blocks 54 are formed with through holes 66 for passing support parts 64 at the front end sides of the setscrews 62. The through holes 66 are bearings for the support parts 64. The setscrews 62 are provided with support parts 64, threaded parts 68 of a larger diameter than the support parts 64, and screw holes 69 at the centers of the support parts 64. The screw holes 69 is screwed by the setscrews 70. The attenuation blocks 54 are constrained by the support parts 64. The side plates 44 and 46 of the housing 4 are formed with threaded parts 72 for fastening the threaded parts 68 of the setscrews 62.

As shown in FIG. 10, at the threaded parts 72 of the side plates 44 and 46 of the housing 4, setscrews 62 are attached from outside of the housing 4. The support parts 64 of the setscrews 62 which stick out into the housing 4 are inserted into the through holes 6 of the attenuation blocks 54. After that, attaching the setscrews 70 to the screw holes 70 of the support parts 64, the attenuation blocks 54 are supported by the support parts 64 of the setscrews 62. If the support parts 64 of the setscrews 62 are smaller in diameter than the through holes 66, the setscrews 62 can be freely turned. If turning the setscrews 62 from outside of the housing 4, the attenuation blocks 54 can be made to move inside the housing 4 in the direction of the arrows X₁, X₂ (FIG. 10). By adjusting the amounts by which the attenuation blocks 54 stick out, it is possible to adjust the space width a₂ of the space 48 and possible to obtain the desired cutoff frequency fc.

The third embodiment is formed so that the amounts by which the projections 38 (FIG. 2, FIG. 3, and FIG. 4) stick out into the housing can be adjusted. Since attenuation blocks 54 is set to be changed in position at the housing 4, is changing the positions of the attenuation blocks 54, it is possible to adjust the space width a₆ to set a desired cutoff frequency and attenuation amount.

### A Fourth Embodiment

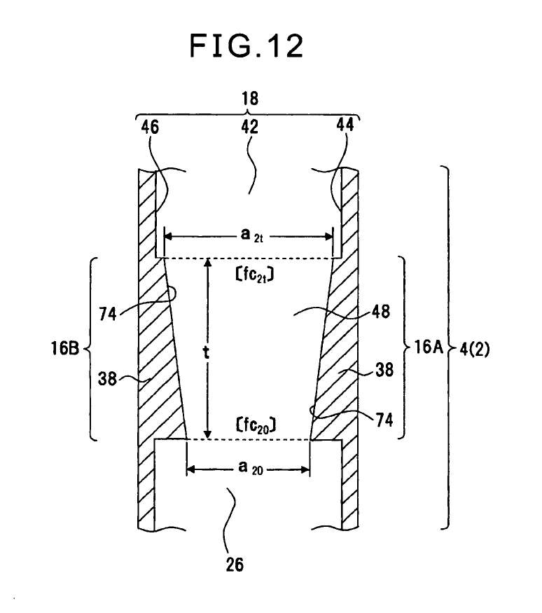

FIG. 11 illustrates the housing and electromagnetic wave attenuation parts of a housing of a communication module according to a fourth embodiment, while FIG. 12 illustrates an attenuated state of electromagnetic waves by the fourth embodiment. In FIG. 11 and FIG. 12, parts the same as in FIG. 1 and FIG. 2 are assigned the same reference notations.

In the fourth embodiment, as shown in FIG. 11, the facing surfaces of the projections 38 which are formed at the side plates 44, 46 of the housing 4 are formed as slanted surfaces 74. These slanted surfaces 74 are examples of the means for continuously increasing or decreasing the cutoff frequency fc in the direction of propagation of the electromagnetic wave 36 through the aperture width (space width) a₂ set inside of the housing 4.

Regarding the width between projections 38 of the electromagnetic wave attenuation parts 16A and 16B, as shown in FIG. 12, if designating the narrowest width due to the slanted surfaces 74 as “a₂₀” and the broadest width as “a₂ₜ, the space width continuously changes from the width a₂₀ to the width a₂ₜ in the section of the length “t” of the projections 38. For this reason, if designating the cutoff frequency at the width a₂₀ as “fc₂₀” and designating the cutoff frequency at the width a₂ₜ as “fc₂ₜ”, the cutoff frequencies of the electromagnetic wave attenuation parts 16A and 16B are distributed between fc₂₀ to fc₂ₜ and attenuation occurs in the zone of the length “t”.

The fourth embodiment has the facing surfaces of the projections 38 (FIG. 2 and FIG. 3) configured tapered. If forming the facing surfaces of the projections 38 as slanted surfaces 74, attenuation in a broad frequency band is obtained in a section of the length “t” changing from the space width a₂₀ to width a₂₁ in the space 48.

### A Fifth Embodiment

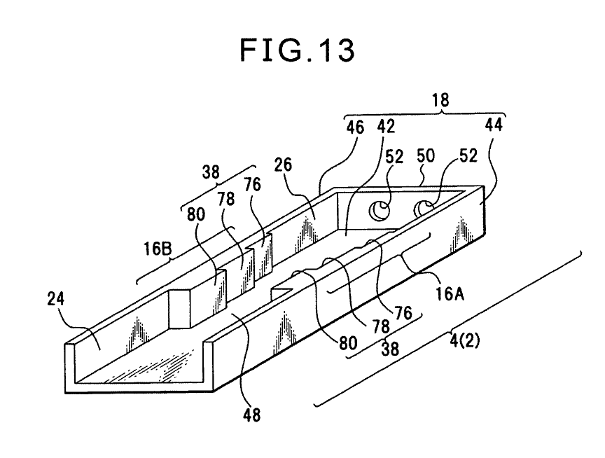

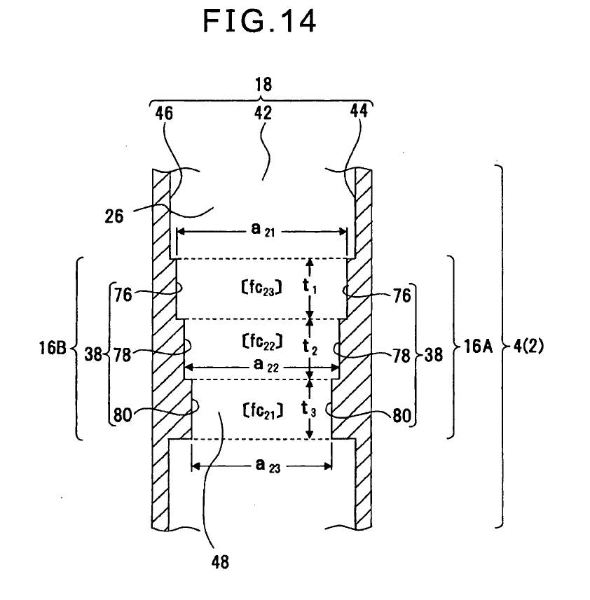

FIG. 13 illustrates the housing and electromagnetic wave attenuation parts of a housing of a communication module according to a fifth embodiment, while FIG. 14 illustrates an attenuated state of electromagnetic waves according to the fifth embodiment. In FIG. 13 and FIG. 14, parts the same as in FIG. 1 and FIG. 2 are assigned the same reference notations.

In the fifth embodiment, as shown in FIG. 13, the facing surfaces of the projections 38 which are formed at the side plates 44 and 46 of the housing 4 are formed as a plurality of step parts, for example, as three step parts 76, 78, and 80. These step parts 76, 78, and 80 are an example of the means for increasing or decreasing the cutoff frequency fc in stages in the direction of propagation of the electromagnetic waves 36 through the aperture width (space width) a₂ set inside of the housing 4.

As shown in FIG. 14, if designating the lengths of the step parts 76, 78, and 80 as t₁, t₂, and t₃ (t₁=t₂=t₃ or t₁≠t₂≠t₃) with respect to the length “t” of the projections 38, then

t=t₁+t₂+t₃ (15)

If designating the aperture widths of the lengths t₁, t₂, and t₃ as a₂₁, a₂₂, and a₂₃, the cutoff frequency fc between the projections 38 of the electromagnetic wave attenuation parts 16A and 16B is found by fc₂≠c/2a₂ of equation (7) and becomes fc₂₁, fc₂₂, and fc₂₃ (fc₂₁<fc₂₂<fc₂₃). In this way, the cutoff frequencies fc₂₁, fc₂₂, and fc₂₃ of the electromagnetic wave attenuation parts 16A and 16B are distributed in the section of the length “t” and attenuation occurs in the section of the length “t”.

Thus, when forming a plurality of step parts 76, 78, and 80 at the facing surfaces of the projections 38, attenuation in a broad frequency band is obtained in a section of the length “t” changing to the space widths a₂₁, a₂₂, and a₂₃ in the space 48.

It is possible to use the projections 38 formed into the step shapes so as to set a plurality of cutoff frequencies differing in steps, so it is possible to obtain an attenuation amount in a broad frequency range.

(1) In the above embodiments, as the communication module, an optical communication module was illustrated, but the communication module of the present disclosure is not limited to this. The disclosure also applies to other communication media such as electromagnetic waves.

(2) In the above embodiments, the electromagnetic wave generation source was inside the housing 4, but the disclosure is not limited to an electromagnetic wave generation source inside the housing 4. There are cases where there is an electromagnetic wave generation source outside of the housing 4. When electromagnetic waves are generated from a part coupled to an outside electromagnetic wave generation source, for example, a connector or wiring member, sometimes electromagnetic waves are generated from the part coupled to the outside electromagnetic wave generation source.

(3) In the above embodiments, examples of changing the width “a” as the space width between the electromagnetic wave attenuation parts 16A and 16B were shown, but it is also possible to change the side plate width “b”.

(4) In the above embodiments, a rectangular waveguide was illustrated as the space in the electromagnetic wave attenuation parts 16A and 16B, but it may also be a circular waveguide.

(5) In the above embodiments, the electromagnetic wave attenuation parts 16A and 16B were configured by setting projections 38 or attenuation blocks 54 at the inside walls of the side plates 44 and 46 of the housing 4, but the disclosure is not limited to this. It is also possible to configure the module to reduce the distance between the side plates 44 and 46 which sandwich the LD driver or other electromagnetic wave generation source within a predetermined range (section of length “t”).

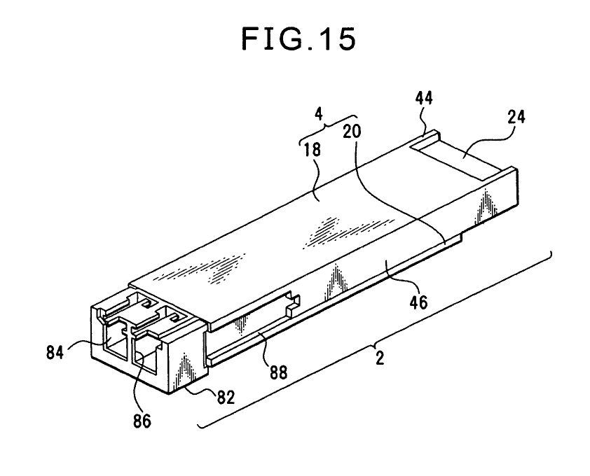

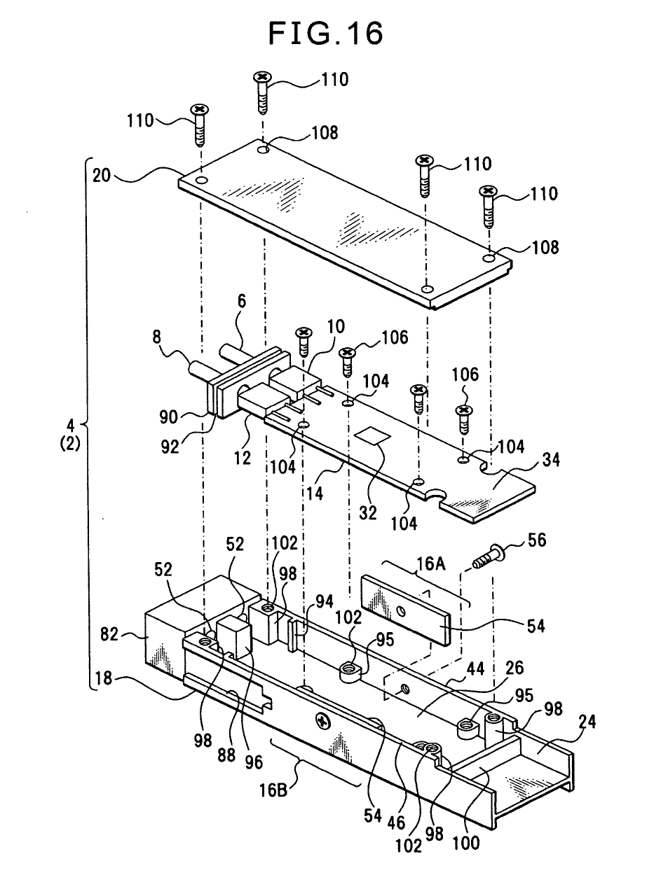

FIG. 15 illustrates a specific example of a communication module, while FIG. 16 illustrates a disassembled communication module of this specific example. In FIG. 15 and FIG. 16, parts the same as in FIG. 1, FIG. 2, and FIG. 7 are assigned the same reference notations.

The communication module 2 of this specific example, as shown in FIG. 15, is comprised of a housing 4 provided with a main body 18 and a lid 20 and is provided with a connector housing 82 which closes the front of the main body 18. The connector housing 82 may be formed by the same metal material as the housing 4. The connector housing 82 has connector plug-in holes 84 and 86. At the back part of the housing 4, a back aperture 24 is formed. Engagement grooves 88 is formed in the side plates 44 and 46 to engage the communication module 2 to the communication device side.

In the space 26 of the main body 18, as shown in FIG. 16, optical connectors 6 and 8, an optical transmitter 10, an optical receiver 12, and a circuit board 14 combined in a circuit component are provided. The optical connectors 6 and 8 have a rectangular support plate 90 attached to them. In the grooves 92 of this support plate 90, engagement parts 94 of the main body 18 which stick out to the insides of the side plates 44 and 46 are inserted. The optical connectors 6 and 8 are inserted into the openings 52 at the back surface side of the connector housing 82 and are inserted into the connector plug-in holes 84 and 86 of the connector housing 82.

In the space 26 of the main body 18, a plurality of fastening parts 94 for fastening the circuit board 14 and a separating wall 96 for separating the optical connectors 6 and 8 are provided. Further, in the space 26 of the main body 18, a plurality of fastening parts 98 for attaching the lid 20 and a separating wall 100 for separating the connector 34 at the circuit board 14 and the space 26 are provided. The separating wall 100 serves also as the supporting means for the circuit board 14. The fastening parts 95 serve also as the support parts 30 illustrated in FIG. 1.

In the space 26, the attenuation blocks 54 which form the magnetic wave attenuation parts 16A and 16B are fastened by setscrews 56. This fastening structure is similar to that of the second embodiment, so the same reference notations are assigned and explanations are omitted.

The fastening parts 95, compared with the fastening parts 98, are provided with a height of about ½ that of the latter and support the circuit board 14 in the middle of the main body 18. The fastening parts 95 and 98 are provided with screw holes 102. Setscrews 106 which are passed through the through holes 104 of the circuit board 14 are used to fasten the circuit board 14 to the fastening parts 95. The connector 34 at the circuit board 14 is arranged at the back aperture 24 of the housing 4. Further, at the fastening parts 98, the lid 20 is fastened by setscrews 110 passed through the through holes 108.

Further, the circuit board 14 is set with an LD driver 32. The driver 32 works as an electromagnetic wave generation source.

In the communication module 2 of a specific example, the electromagnetic waves which are emitted from the LD driver 32 are attenuated inside of the housing 4 at the cutoff frequency set by the electromagnetic wave attenuation parts 16A and 16B which are fastened by the setscrews and the frequency band including that cutoff frequency so it is possible to prevent spurious emissions from the back aperture 24.

In the specific example illustrated in FIGS. 15 and 16, spurious emissions from the front aperture 22 are suppressed by attenuation of the electromagnetic waves and suppression of spurious emissions by the electromagnetic wave attenuation parts 16A and 16B and by suppression of spurious emissions by the connector housing 82 closing the front aperture 22 of the housing 4. However, even if the front aperture 22 is in the open state, due to the function of the electromagnetic wave attenuation parts 16A and 16B in attenuating the electromagnetic waves and suppressing spurious emissions, it is possible to prevent spurious emissions from the front aperture 22 needless to say.

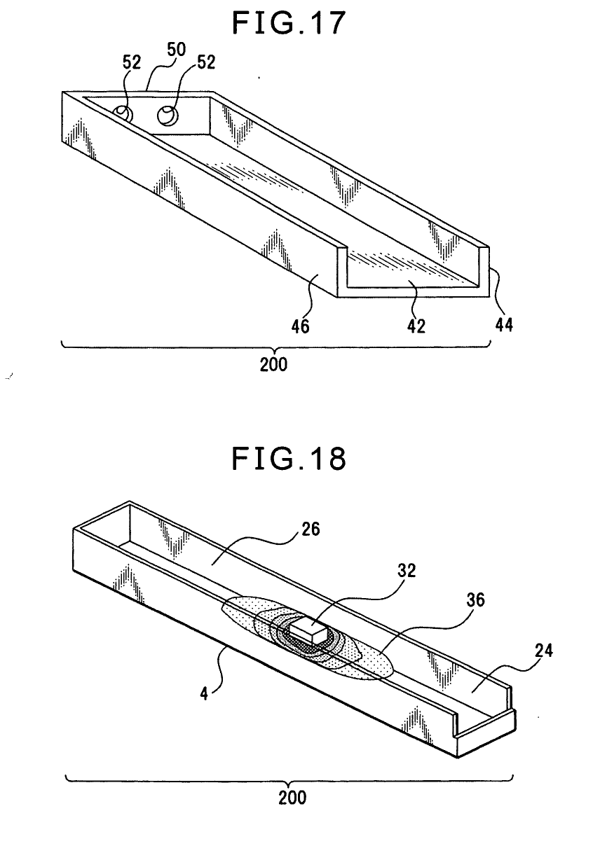

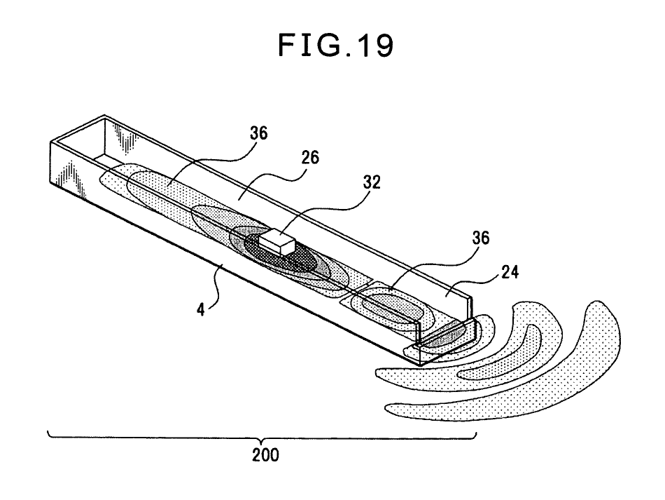

FIGS. 17 to 19 are views which explain a comparative example of an XFP (10 Gigabit Small Form Factor Pluggable) module. FIG. 17 illustrates the housing of the XFP module, while FIG. 18 and FIG. 19 illustrate the states of propagation and leakage of electromagnetic waves of the XFP module.

The housing 4 of this XFP module 200, as shown in FIG. 17, is provided with a plate part 42 and side plates 44, 46, and 50. The electromagnetic wave attenuation parts 16A and 16B are not provided.

This housing 4 houses an LD driver 32 or other electromagnetic wave generation source. For example, if assuming that a short pulse electromagnetic waves 36 with a center frequency of 5 GHz is generated, as shown in FIG. 18, the electromagnetic wave spreads and is propagated along the space 26 of the housing 4. The closer to the electromagnetic wave generation source (LD driver 32), the stronger the electrical field strength.

Further, for example, if a short pulse electromagnetic wave 36 with a center frequency of 10 GHz is generated, as illustrated in FIG. 19, the electromagnetic wave 36 spreads and is propagated along the space 26 of the housing 4 whereby spurious emissions occur from the back aperture 24. The closer to the electromagnetic wave generation source, the stronger the electrical field strength. In this case, the electromagnetic waves are not attenuated and spurious emissions having a strong electrical field strength occur.

As opposed to this, if providing the projections 38 in the housing 4, electromagnetic wave attenuation parts 16A and 16B is formed. The electromagnetic wave attenuation parts 16A, 16B defines a space having a cutoff frequency determined by the interval between the projections 38 and an attenuation amount determined by the long direction of the projections 38. As explained above, for example, if the interval “a₂”=12 mm and the length “t”=30 mm or so, it is possible to attenuate an electromagnetic wave 36 of a frequency of 10 GHz by 20 dB or more.

In the above embodiments, a specific communication module was described, but it is possible to apply the present disclosure in the same way to the same type of communication module, for example, using a universal serial bus (USB).

According to the communication module of the present disclosure, the following effects can be obtained.

(1) The electromagnetic wave attenuation parts are provided inside the housing of the communication module, so the electromagnetic waves forming spurious emissions are attenuated in the housing, whereby it is possible to suppress spurious emissions of electromagnetic waves to the outside of the housing and possible to improve the EMI characteristics.

(2) No member for absorbing the electromagnetic waves is provided outside of the housing, so reduction of size of the communication module is not obstructed.

All examples and conditional language recited herein are intended for pedagogical purposes to aid the reader in understanding the disclosure and the concepts contributed by the inventor to furthering the art and are to be construed as being without limitation to such specifically recited examples and conditions. Nor does the organization of such examples in the specification relate to a showing of the superiority and inferiority of the disclosure. Although the embodiments and examples have been described in detail, it should be understood that the various changes, substitutions, and alterations could be made hereto without departing from the spirit and scope of the disclosure.

1. A communication module comprising:
a communication circuit;
a connector coupled to the communication circuit;
a housing having a space for arranging the communication circuit and an aperture for arranging the connector; and
a projection provided at facing inside wall surface of the housing and attenuating an electromagnetic wave within a frequency range transmitted in the space.

2. The communication module according to claim 1, wherein the projection is formed integrally with the housing or a unit formed separately from the housing.

3. The communication module according to claim 1, wherein the projection includes projection parts facing each other and respectively projecting from an inner surface of the housing into the space.

4. The communication module according to claim 3, wherein each of the projection parts is movable in a projecting direction so as to change a projection length of each of the projection parts.

5. The communication module according to claim 3, wherein each of the projection parts has a slanted surface continuously changing an interval between the projection parts.

6. The communication module according to claim 3, wherein each of the projection parts has a step-like surface stepwisely changing an interval between the projection parts.
